(19) United States
(12) Patent Application Publication
(10) Pub. No.: US 2012/0162849 A1
(43) Pub. Date: Jun. 28, 2012

(54) ELECTRONIC DEVICE

(75) Inventor: XING-HUA TANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/217,124

(22) Filed: Aug. 24, 2011

(30) Foreign Application Priority Data
Dec. 23, 2010 (CN) 201010602790.2

(51) Int. Cl. H05F 3/00; H03L 7/00

(52) U.S. Cl. 361/220; 327/142

(57) ABSTRACT

An electronic device includes a processing unit and a register. The processing unit reads information from the register, and generates a reset signal when detecting an error generated by the register, the register is reset according to the reset signal.

### BACKGROUND

1. Technical Field

The disclosed embodiments relate to an electronic device.

2. Description of Related Art

Touch pads are becoming increasingly popular because of their ease of use, versatility, and low price. A touch pad is often incorporated in electronic devices, such as mobile phones, and used as an input device to move a screen pointer.

A capacitive touch pad includes a ground wire, the ground wire is used for discharging electrostatic discharge (ESD) surges applied to the touch pad. A capacitor is formed between the ground wire and the conducting wires of the touch pad, however, if the size of the ground wire is too large, the capacitance of the capacitor is also too large and may affect the performance of the touch pad. If the size of the ground wire is too small, the ground wire cannot discharge ESD surges in time, thus causing the touch pad to malfunction.

Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout two views.

FIG. 1 is a block diagram of an electronic device in accordance with one embodiment.

FIG. 2 is a detailed block diagram of the electronic device in FIG. 1.

### DETAILED DESCRIPTION

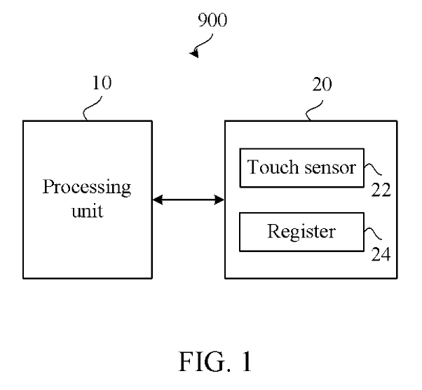

Referring to FIG. 1, an electronic device 900 includes a processing unit 10 and a touch pad 20. The touch pad 20 includes a touch sensor 22 and a register 24. The touch sensor 22 detects physical touches from users, and generates touch signals. The register 24 stores information generated by the touch sensor 22. The processing unit 10 performs functions in response to the touch signals. When ESD surges are applied to the touch pad 20, an error may be generated by the register 24. In other embodiments, the touch pad 20 is not incorporated in the electronic device 900.

The processing unit 10 further reads information from the register 24 every predetermined time period, and generates a reset signal when an error is detected. In this embodiment, the error prevents the processing unit 10 from reading any information from the register 24, and the predetermined time period is less than one second. The touch pad 20 is reset according to the reset signal, thus restoring the touch pad 20 to initial conditions.

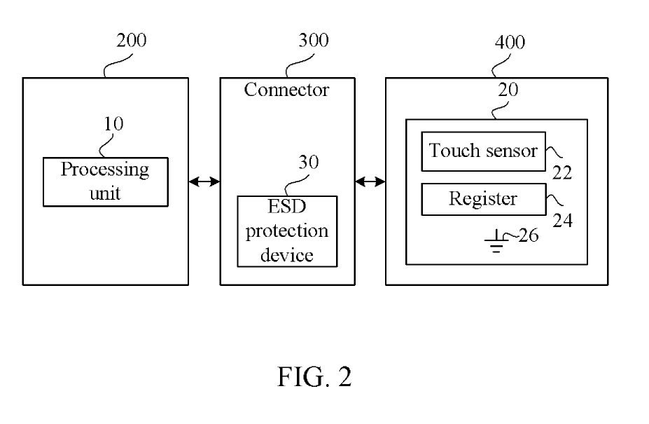

Referring to FIG. 2, the processing unit 10 is disposed on a first printed circuit board (PCB) 200, the touch pad 20 is disposed on a second PCB 400, the first PCB 200 is connected to the second PCB 400 through a connector 300. The connector 300 includes an ESD protection device 30 for providing ESD shielding between the first PCB 200 and the second PCB 300, therefore any ESD surges applied to the touch pad 20 cannot be transmitted from the second PCB 300 to the first PCB 200, and the processing unit 10 is effectively protected.

In this embodiment, the touch pad 20 is a capacitive touch pad. The touch pad 20 further includes a ground wire 26, and the ground wire 26 is used for discharging ESD surges applied to the touch pad 20. In effect, a capacitor is formed between the ground wire and conducting wires of the touch pad 20. In this embodiment, the size of the ground wire is small.

Firstly, because the size of the ground wire 26 is small, the ground wire 26 cannot discharge the ESD surges in time, and the touch pad 20 may malfunction due to ESD. Because the processing unit 10 reads information from the register 22 every predetermined time period, when the touch pad 20 malfunctions, the processing unit 10 cannot read information from the register 24 and generates the reset signal, the touch pad 20 is reset according to the reset signal, and then the touch pad 20 is enabled and operates normally. At the same time, during the predetermined time period, the electrostatic surge current is conducted to ground through the ground wire 26, and ESD surges are effectively removed.

Secondly, because the size of the ground wire 24 is small, thus the capacitance of the capacitor is also small, and such a capacitor cannot affect the performance of the touch pad 20.

Alternative embodiments will apparent to those skilled in the art without departing from the spirit and scope of what is claimed. Accordingly, the present invention should be deemed not to be limited to the above detailed description, but rather only by the claims that follow and equivalents thereof.

What is claimed is:

1. An electronic device, comprising:
a processing unit; and
a register;
wherein the processing unit reads information from the register, and generates a reset signal when detecting an error generated by the register, the register is reset according to the reset signal.

2. The electronic device of claim 1, wherein the processing unit reads information from the register every predetermined time period.

3. The electronic device of claim 2, wherein the predetermined time period is less than one second.

4. The electronic device of claim 1, wherein the processing unit is disposed on a first printed circuit board (PCB), the register is disposed on a second PCB, the first PCB is connected to the second PCB through a connector.

5. The electronic device of claim 4, wherein the connector comprises an electrostatic discharge (ESD) protection device for providing ESD shielding between the first PCB and the second PCB.

6. The electronic device of claim 1, further comprising a touch pad, wherein the touch pad is a capacitive touch pad, the touch pad comprises a ground wire, when ESD surges are applied to the touch pad, the ground wire is used for conducting electrostatic surge current to ground.

7. The electronic device of claim 6, wherein a capacitor is formed between the ground wire and conducting wires of the touch pad, the capacitor cannot affect performance of the touch pad.

8. The electronic device of claim 1, wherein the error indicates that the processing unit cannot read the information from the register.

9. The electronic device of claim 1, wherein the error is generated by the register due to ESD.

10. An electronic device, comprising:
a processing unit connected to a register;
wherein the processing unit reads information from the register, and generates a reset signal when detecting an error generated by the register, the register is reset according to the reset signal.

11. The electronic device of claim 10, wherein the processing unit reads information from the register every predetermined time period.

12. The electronic device of claim 11, wherein the predetermined time period is less than one second.

13. The electronic device of claim 10, wherein the processing unit is disposed on a first PCB, the register is disposed on a second PCB, the first PCB is connected to the second PCB through a connector.

14. The electronic device of claim 13, wherein the connector comprises an ESD protection device for providing ESD shielding between the first PCB and the second PCB.

15. The electronic device of claim 10, wherein the register is a component in a touch pad, the touch pad further comprises a ground wire, wherein the touch pad is a capacitive touch pad, the ground wire is used for discharging ESD surges applied to the touch pad.

16. The electronic device of claim 15, wherein a capacitor is formed between the ground wire and conducting wires of the touch pad, the capacitor cannot affect performance of the touch pad.

17. The electronic device of claim 10, wherein the error indicates that the processing unit cannot read the information from the register.

18. The electronic device of claim 10, wherein the error is generated by the register due to ESD.
